(19) United States
(12) Patent Application Publication
(10) Pub. No.: US 2024/0276744 A1
(43) Pub. Date: Aug. 15, 2024

(54) IMAGING APPARATUS

(71) Applicant: Panasonic Intellectual Property Management Co., Ltd., Osaka (JP)

(72) Inventors: MORIO MITSUISHI, Kanagawa (JP); TAKAMICHI YOKOYAMA, Kanagawa (JP); HIROAKI IIJIMA, Nara (JP)

(21) Appl. No.: 18/626,366

(22) Filed: Apr. 4, 2024

Related U.S. Application Data
(63) Continuation of application No. PCT/JP2022/035984, filed on Sep. 27, 2022.

(30) Foreign Application Priority Data
Oct. 26, 2021 (JP) 2021-174266

(51) Int. Cl. H10K 30/85; H10K 39/32

(52) U.S. Cl. CPC H10K 30/85; H10K 39/32

(57) ABSTRACT

An imaging apparatus includes a first electrode, a second electrode, a photoelectric conversion layer, a charge injection layer, and a charge accumulation region. The second electrode opposes the first electrode. The photoelectric conversion layer is located between the first electrode and the second electrode, contains a donor semiconductor material and an acceptor semiconductor material, and generates a pair of an electron and a hole. The charge injection layer is located between the first electrode and the photoelectric conversion layer. The charge accumulation region is electrically coupled to the second electrode and accumulates the hole. An ionization potential of the charge injection layer is less than or equal to an ionization potential of the acceptor semiconductor material. Electron affinity of the charge injection layer is less than or equal to electron affinity of the acceptor semiconductor material. Light transmittance of the charge injection layer is greater than or equal to 70%.

### BACKGROUND

### 1. Technical Field

The present disclosure relates to an imaging apparatus including a photoelectric conversion element.

### 2. Description of the Related Art

Organic semiconductor materials have physical properties, functions, and the like which are not provided to inorganic semiconductor materials, such as silicon, in the related art and have been intensively researched as semiconductor materials capable of realizing new semiconductor devices and electronic equipment.

For example, photoelectric conversion elements in which an organic semiconductor material is used as a material for forming a photoelectric conversion layer have been researched. A photoelectric conversion element being irradiated with light generates a pair of electron and a hole called an exciton. As described in Yuliar Firdaus et al., “Long-range exciton diffusion in molecular non-fullerene acceptors”, nat. comm., 11:5220, 2020, the generated exciton diffuses a distance of about 5 nm to 20 nm and reaches the interface between a donor material and an acceptor material so that charge separation occurs and an electron and a hole are generated. The interface between a donor material and an acceptor material is also called a donor-acceptor interface. The photoelectric conversion element can be utilized as an imaging apparatus and the like by the generated electron or the hole being removed as a signal charge. Regarding the photoelectric conversion element used for the imaging apparatus and the like, to improve the sensitivity, it is desirable that a charge be efficiently generated and removed to an electrode.

In response to such a demand, for example, Japanese Unexamined Patent Application Publication No. 2014-22525 proposes a method in which a charge-blocking layer and a charge-transport auxiliary layer are disposed in the photoelectric conversion element. The charge-blocking layer is disposed between an electrode and a photoelectric conversion layer. The charge-blocking layer prevents a charge from flowing backward from the electrode when a bias voltage is applied to the photoelectric conversion element. In this regard, the charge-transport auxiliary layer is disposed between the charge-blocking layer and the photoelectric conversion layer and assists transportation of the electron or the hole generated through photoelectric conversion to the electrode.

### SUMMARY

In one general aspect, the techniques disclosed here feature an imaging apparatus including a first electrode, a second electrode facing the first electrode, a photoelectric conversion layer that is located between the first electrode and the second electrode, that contains a donor semiconductor material and an acceptor semiconductor material, and that generates a pair of an electron and a hole, a charge injection layer located between the first electrode and the photoelectric conversion layer, and a charge accumulation region that is electrically coupled to the second electrode and that accumulates the hole. An ionization potential of the charge injection layer is less than or equal to an ionization potential of the acceptor semiconductor material. Electron affinity of the charge injection layer is less than or equal to electron affinity of the acceptor semiconductor material. Light transmittance of the charge injection layer is greater than or equal to 70%.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic sectional view illustrating a configuration of a photoelectric conversion element according to an embodiment;

FIG. 2 is an exemplary energy band diagram in the photoelectric conversion element illustrated in FIG. 1;

FIG. 3 is a diagram illustrating an example of a circuit configuration of an imaging apparatus according to an embodiment;

FIG. 4 is a schematic sectional view illustrating a device structure of a pixel in an imaging apparatus according to an embodiment; and

FIG. 5 is an exemplary energy band diagram in another photoelectric conversion element according to an embodiment.

### DETAILED DESCRIPTIONS

Even an imaging apparatus in which an photoelectric conversion element including a charge-blocking layer, a charge-transport auxiliary layer, and the like is used as the photoelectric conversion element, as described in Japanese Unexamined Patent Application Publication No. 2014-22525, is not limited to being capable of sufficiently improving the sensitivity.

According to the present disclosure, the sensitivity of an imaging apparatus can be improved.

### Underlying Knowledge Forming Basis of Aspect According to the Present Disclosure

The present inventors found that the method disclosed in Japanese Unexamined Patent Application Publication No. 2014-22525 has the following problem. In general, the diffusion length of an exciton of an organic semiconductor is about 5 nm to 20 nm, and when a distance from the position at which the light is absorbed to the donor-acceptor interface for dissociating the exciton is greater than the diffusion length, the exciton is deactivated so that photoelectric conversion does not occur. Regarding the method disclosed in Japanese Unexamined Patent Application Publication No. 2014-22525, a portion of excitons generated in a region near to the charge-transport auxiliary layer in the organic photoelectric conversion layer cannot reach the donor-acceptor interface due to scattering into the charge-transport auxiliary layer. That is, the charge-transport auxiliary layer being disposed improves the transportation efficiency after charge separation of the exciton, but the charge separation efficiency is not improved.

Therefore, in the photoelectric conversion layer, to improve the charge separation efficiency and to obtain high sensitivity, it is useful to efficiently cause charge separation of the exciton in the region near to the interface between the photoelectric conversion layer and another layer such as the charge-transport auxiliary layer. For example, when the light is incident from the charge-transport auxiliary layer side of the photoelectric conversion layer, since the light is absorbed, at first, in the region near to the charge-transport auxiliary layer in the photoelectric conversion layer, in particular, it is desirable that the exciton in this region efficiently undergo charge separation. In Japanese Unexamined Patent Application Publication No. 2014-22525, there is no description on a method for effectively improving the charge separation efficiency while the effect of the charge-blocking layer or the charge-transport auxiliary layer is maintained.

The present disclosure was realized on the basis of such findings and provides an imaging apparatus capable of improving the sensitivity by efficiently causing charge separation of the exciton generated in the vicinity of the interface between the photoelectric conversion layer and another layer, in the photoelectric conversion layer.

### Outline of the Present Disclosure

The outline of an aspect according to the present disclosure is as described below.

An imaging apparatus according to an aspect of the present disclosure includes a first electrode, a second electrode facing the first electrode, a photoelectric conversion layer that is located between the first electrode and the second electrode, that contains a donor semiconductor material and an acceptor semiconductor material, and that generates a pair of an electron and a hole, a charge injection layer located between the first electrode and the photoelectric conversion layer, and a charge accumulation region that is electrically coupled to the second electrode and that accumulates the hole. An ionization potential of the charge injection layer is less than or equal to an ionization potential of the acceptor semiconductor material. Electron affinity of the charge injection layer is less than or equal to electron affinity of the acceptor semiconductor material. Light transmittance of the charge injection layer is greater than or equal to 70%.

Accordingly, photoelectric conversion occurs due to charge separation between the acceptor semiconductor material contained in the photoelectric conversion layer and a material contained in the charge injection layer, and the sensitivity of the imaging apparatus can be improved. Specifically, an exciton generated by light absorption of the acceptor semiconductor material contained in the photoelectric conversion layer diffuses to the interface to the charge injection layer. Since the relationship between the energy band of the charge injection layer and the energy band of the acceptor semiconductor material is as described above, an electron is left in the acceptor semiconductor material, and a hole is moved to the charge injection layer so that the pair of the electron and the hole serving as the exciton is dissociated at the interface. The separated hole performs hopping conduction in the photoelectric conversion layer due to, for example, a voltage applied between the first electrode and the second electrode and is collected by the second electrode so as to be accumulated in the charge accumulation region. Consequently, since the hole separated at the interface between the acceptor semiconductor material and the charge injection layer can also be utilized as a signal charge, the sensitivity of the imaging apparatus can be improved. In addition, since the charge injection layer can suppress a charge from being injected from the first electrode to the photoelectric conversion layer, noise signal which affects the SN ratio can be decreased. In addition, the charge injection layer becoming difficult to absorb light is compatible with the sensitivity of the imaging apparatus being improved due to the exciton generated in the charge injection layer diffusing and reaching the interface to the acceptor semiconductor material of the photoelectric conversion layer.

For example, the volume proportion of the acceptor semiconductor material in the photoelectric conversion layer may be greater than or equal to 70%.

Accordingly, since the contact interface between the acceptor semiconductor material and the charge injection layer in which charge separation of an exciton occurs increases, the sensitivity of the imaging apparatus can be further improved.

For example, the imaging apparatus may further include a charge-blocking layer located between the second electrode and the photoelectric conversion layer, and a value obtained by subtracting the ionization potential of the charge injection layer from an ionization potential of the donor semiconductor material may be less than a value obtained by subtracting the ionization potential of the donor semiconductor material from an ionization potential of the charge-blocking layer.

Accordingly, regarding collection of the hole separated at the interface between the acceptor semiconductor material and the charge injection layer by the second electrode, since a barrier to hopping of the hole from the charge injection layer to the donor semiconductor material of the photoelectric conversion layer is not a rate-limiting factor, the hole can be efficiently collected. In addition, since the charge-blocking layer can also suppress a charge from being injected from the second electrode to the photoelectric conversion layer, noise signal which affects the SN ratio can be decreased.

An imaging apparatus according to another aspect of the present disclosure includes a first electrode, a second electrode facing the first electrode, a photoelectric conversion layer that is located between the first electrode and the second electrode, that contains a donor semiconductor material and an acceptor semiconductor material, and that generates a pair of an electron and a hole, a charge injection layer located between the first electrode and the photoelectric conversion layer, and a charge accumulation region that is electrically coupled to the second electrode and that accumulates the electron. Electron affinity of the charge injection layer is greater than or equal to electron affinity of the donor semiconductor material. An ionization potential of the charge injection layer is greater than or equal to an ionization potential of the donor semiconductor material. Light transmittance of the charge injection layer is greater than or equal to 70%.

Accordingly, photoelectric conversion occurs between the donor semiconductor material contained in the photoelectric conversion layer and a material contained in the charge injection layer, and the sensitivity of the imaging apparatus can be improved. Specifically, an exciton generated by light absorption of the donor semiconductor material contained in the photoelectric conversion layer diffuses to the interface to the charge injection layer. Since the relationship between the energy band of the charge injection layer and the energy band of the donor semiconductor material is as described above, a hole is left in the donor semiconductor material, and an electron is moved to the charge injection layer so that the pair of the electron and the hole serving as the exciton is dissociated at the interface. The separated electron performs hopping conduction in the photoelectric conversion layer due to, for example, a voltage applied between the first electrode and the second electrode and is collected by the second electrode so as to be accumulated in the charge accumulation region. Consequently, since the electron separated at the interface between the donor semiconductor material and the charge injection layer can also be utilized as a signal charge, the sensitivity of the imaging apparatus can be improved. In addition, since the charge injection layer can suppress a charge from being injected from the first electrode to the photoelectric conversion layer, noise signal which affects the SN ratio can be decreased. In addition, the sensitivity of the imaging apparatus is suppressed from deteriorating due to an amount of the light incident on the photoelectric conversion layer being decreased.

For example, the volume proportion of the donor semiconductor material in the photoelectric conversion layer may be greater than or equal to 70%.

Accordingly, since the contact interface between the donor semiconductor material and the charge injection layer in which charge separation of an exciton occurs increases, the sensitivity of the imaging apparatus can be further improved.

For example, the imaging apparatus may further include a charge-blocking layer located between the second electrode and the photoelectric conversion layer, and a value obtained by subtracting the electron affinity of the charge injection layer from electron affinity of the acceptor semiconductor material may be greater than a value obtained by subtracting the electron affinity of the acceptor semiconductor material from electron affinity of the charge-blocking layer.

Accordingly, regarding collection of the electron separated at the interface between the donor semiconductor material and the charge injection layer by the second electrode, since a barrier to hopping of the electron from the charge injection layer to the donor semiconductor material of the photoelectric conversion layer is not a rate-limiting factor, the electron can be efficiently collected. In addition, since the charge-blocking layer can also suppress a charge from being injected from the second electrode to the photoelectric conversion layer, noise signal which affects the SN ratio can be decreased.

For example, light transmittance in the visible light region of the charge injection layer may be greater than or equal to 70%.

Accordingly, the sensitivity of the imaging apparatus can be suppressed from deteriorating due to an amount of the light incident on the photoelectric conversion layer being decreased.

For example, a thickness of the charge injection layer may be greater than or equal to 2 nm.

Accordingly, a function of suppressing a charge from being injected from the first electrode to the photoelectric conversion layer of the charge injection layer is readily ensured.

For example, the thickness of the charge injection layer may be less than 20 nm.

Accordingly, since the charge injection layer becomes difficult to absorb light, the sensitivity of the imaging apparatus can be suppressed from deteriorating due to an amount of the light incident on the photoelectric conversion layer being decreased.

An imaging apparatus according to another aspect of the present disclosure includes a first electrode, a second electrode facing the first electrode, a photoelectric conversion layer that is located between the first electrode and the second electrode, that contains a donor semiconductor material and an acceptor semiconductor material, and that generates a pair of an electron and a hole, a charge injection layer located between the first electrode and the photoelectric conversion layer, and a charge accumulation region that is electrically coupled to the second electrode and that accumulates the hole. An ionization potential of the charge injection layer is less than or equal to an ionization potential of the acceptor semiconductor material. Electron affinity of the charge injection layer is less than or equal to electron affinity of the acceptor semiconductor material. A thickness of the charge injection layer is greater than or equal to 2 nm and less than 20 nm.

Accordingly, the charge injection layer becoming difficult to absorb light is compatible with the sensitivity of the imaging apparatus being improved due to the exciton generated in the charge injection layer diffusing and reaching the interface to the acceptor semiconductor material of the photoelectric conversion layer.

The embodiments will be described below with reference to the drawings.

In this regard, all the embodiments described below indicate comprehensive or specific examples. Numerical values, shapes, constituents, arrangement positions and connection forms of the constituents, steps, step sequence, and the like described in the following embodiments are exemplifications and are not intended to limit the present disclosure. In this regard, of the constituents in the following embodiments, the constituents not described in the independent claims are described as optional constituents. In addition, cach drawing is not limited to being precisely drawn. In the drawings, substantially the same configurations may be denoted by the same references, and duplicate explanations may be omitted or simplified.

In the present specification, terms indicating the relationship between elements, terms indicating the shapes of elements, and numerical ranges are not expressions indicating only strict meanings but expressions include substantially equivalent meanings, for example, include a difference of about several %.

In the present specification, terms “up” and “down” do not refer to an upward direction (vertically upward) and a downward direction (vertically downward) based on absolute spatial recognition and are used as terms specified in accordance with relative positional relationship based on the order of stacking with respect to a multilayer configuration. In this regard, the terms “up”, “down”, and the like are only used to specify relative arrangement of members and are not intended to limit the orientation of the imaging apparatus during use. In addition, the terms “up” and “down” are applied to not only the instance in which two constituents are spaced and another constituent is present between the two constituents but also the instance in which two constituents are arranged adhering to each other and the two constituents are in contact with each other.

In the present specification, the general electromagnetic wave including visible light, infrared rays, and ultraviolet rays is expressed as “light” for convenience.

### Embodiments

### Photoelectric Conversion Element

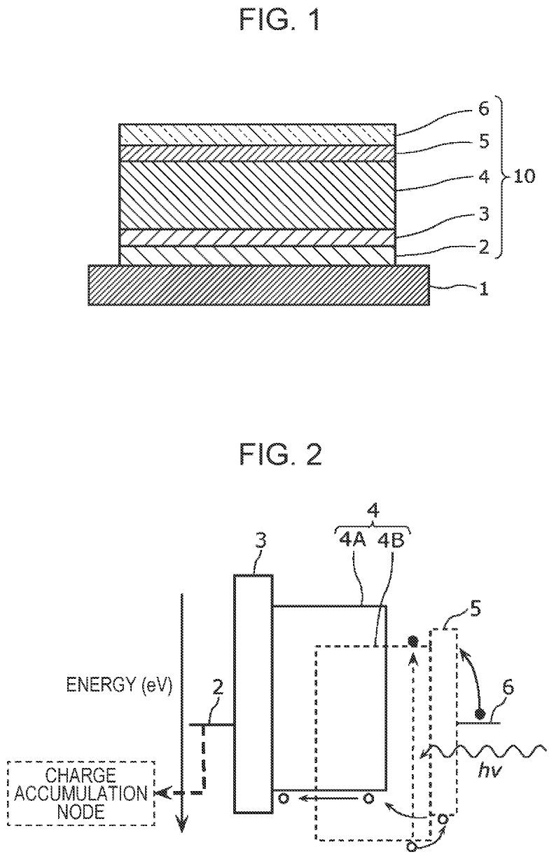

A photoelectric conversion element included in the imaging apparatus according to the present embodiment will be described with reference to FIG. 1. The photoelectric conversion element according to the present embodiment is a photoelectric conversion element of a charge reading system. FIG. 1 is a schematic sectional view illustrating a configuration of a photoelectric conversion element 10 according to the present embodiment.

As illustrated in FIG. 1, the photoelectric conversion element 10 is supported by a support substrate 1 and includes an upper electrode 6 and a lower electrode 2 which serve as a pair of electrodes, a photoelectric conversion layer 4 located between the upper electrode 6 and the lower electrode 2, a charge-blocking layer 3 located between the lower electrode 2 and the photoelectric conversion layer 4, and a charge injection layer 5 located between the photoelectric conversion layer 4 and the upper electrode 6. In the present embodiment, the upper electrode 6 is an example of the first electrode, and the lower electrode 2 is an example of the second electrode.

The photoelectric conversion element 10 is used in an orientation in which, for example, the light passed through the upper electrode 6 and the charge injection layer 5 is incident on the photoelectric conversion layer 4.

Each constituent of the photoelectric conversion element 10 according to the present embodiment will be described below.

It is sufficient that the support substrate 1 is a substrate used for supporting a common photoelectric conversion element and may be, for example, a glass substrate, a quartz substrate, a semiconductor substrate, or a plastic substrate.

The lower electrode 2 is formed of a metal, a metal nitride, a metal oxide, a polysilicon provided with electrical conductivity, or the like. Examples of the metal include aluminum, copper, titanium, and tungsten. Examples of the method for providing the polysilicon with electrical conductivity include doping of an impurity.

The upper electrode 6 is a transparent electrode formed of, for example, a transparent conductive material. Examples of the material for forming the upper electrode 6 include a transparent conducting oxide (TCO), indium tin oxide (ITO), indium zinc oxide (IZO), aluminum-doped zinc oxide (AZO), fluorine-doped tin oxide (FTO), SnO₂, and TiO₂. In this regard, the upper electrode 6 may be appropriately produced from only one of or by combining a plurality of metal materials, such as aluminum (Al) and gold (Au), in accordance with the predetermined transmittance.

The material for forming the lower electrode 2 and the upper electrode 6 is not limited to the above-described conductive materials, and other materials may be used.

Various methods are used for producing the lower electrode 2 and the upper electrode 6 in accordance with the material to be used. For example, when ITO is used, a method, such as an electron beam method, a sputtering method, a resistance-heating vapor deposition method, a chemical reaction method of a sol-gel method or the like, or application of an indium tin oxide dispersion material, may be used. In such an instance, for producing the lower electrode 2 and the upper electrode 6, UV-ozone treatment, plasma treatment, or the like may be further performed after an ITO film is formed.

The photoelectric conversion layer 4 contains a donor semiconductor material and an acceptor semiconductor material. The photoelectric conversion layer 4 is produced by using, for example, an organic semiconductor material. Regarding the method for producing the photoelectric conversion layer 4, for example, a wet method such as a coating method through spin coating or the like or a dry method such as a vacuum vapor deposition method can be used. The vacuum vapor deposition method is a method in which a material for forming the layer is vaporized by being heated in a vacuum so as to be deposited on a substrate.

In addition, the photoelectric conversion layer 4 is, for example, a mixture film having a bulk hetero structure and containing the donor semiconductor material and the acceptor semiconductor material. Specific examples of the donor semiconductor material and the acceptor semiconductor material will be described below.

Examples of the donor semiconductor material include triarylamine compounds, benzidine compounds, pyrazoline compounds, styrylamine compounds, hydrazone compounds, triphenylmethane compounds, carbazole compounds, polysilane compounds, thiophen compounds, phthalocyanine compounds, naphthalocyanine compounds, subphthalocyanine compounds, cyanine compounds, merocyanine compounds, oxonol compounds, polyamine compounds, indole compounds, pyrrole compounds, pyrazole compounds, polyarylene compounds, condensed aromatic carbocyclic compounds, and metal complexes having a nitrogen-containing heterocyclic compound as a ligand.

Examples of the condensed aromatic carbocyclic compound include naphthalene derivatives, anthracene derivatives, phenanthrene derivatives, tetracene derivatives, pyrene derivatives, perylene derivatives, and fluoranthene derivatives.

Examples of the acceptor semiconductor material include fullerene, fullerene derivatives, condensed aromatic carbocyclic compounds, five- to seven-membered heterocyclic compounds containing a nitrogen atom, an oxygen atom, or a sulfur atom, polyarylene compounds, fluorene compounds, cyclopentadiene compounds, silyl compounds, metal complexes having a nitrogen-containing heterocyclic compound as a ligand.

Examples of the fullerene includes fullerene C60 and fullerene C70.

Examples of the fullerene derivative include phenyl-C₆₁-butyric acid methyl ester (PCBM) and indene-C₆₀ bisadduct (ICBA).

Examples of the condensed aromatic carbocyclic compound include naphthalene derivatives, anthracene derivatives, phenanthrene derivatives, tetracene derivatives, pyrene derivatives, perylene derivatives, and fluoranthene derivatives.

Examples of the five- to seven-membered heterocyclic compounds containing a nitrogen atom, an oxygen atom, or a sulfur atom include pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, and tribenzazepine.

In this regard, the donor semiconductor material and the acceptor semiconductor material are not limited to the above-described examples. Low-molecular-weight compounds and high-molecular-weight compounds may be used as the donor semiconductor material and the acceptor semiconductor material constituting the photoelectric conversion layer 4 provided that the compound is an organic compound that can be made into a film as a photoelectric conversion layer by any one of a dry method or a wet method.

In addition, the photoelectric conversion layer 4 may contain, as the donor semiconductor material and the acceptor semiconductor material, a semiconductor material other than the organic semiconductor material. The photoelectric conversion layer 4 may contain, as the semiconductor material, a silicon semiconductor, a compound semiconductor, a quantum dot, a perovskite material, a carbon nanotube, or the like or a mixture of two or more of these.

The proportion of the acceptor semiconductor material in the photoelectric conversion layer 4 is, for example, greater than or equal to 70%. In addition, the donor semiconductor material in the photoelectric conversion layer 4 is, for example, less than or equal to 50% of the acceptor semiconductor material. Consequently, since the contact interface between the acceptor semiconductor material and the charge injection layer 5 increases, an effect of improving the sensitivity, as described later, is obtained more significantly. In this regard, the proportion of the material is, for example, a volume proportion but may be a weight proportion.

The photoelectric conversion element 10 according to the present embodiment includes the charge-blocking layer 3 disposed between the lower electrode 2 and the photoelectric conversion layer 4 and the charge injection layer 5 disposed between the upper electrode 6 and the photoelectric conversion layer 4. The charge-blocking layer 3 is in contact with, for example, the lower electrode 2 and the photoelectric conversion layer 4. The charge injection layer 5 is in contact with, for example, the upper electrode 6 and the photoelectric conversion layer 4.

A semiconductor material having an energy band described later is used as the material for forming the charge-blocking layer 3 and the charge injection layer 5. The charge-blocking layer 3 and the charge injection layer 5 is formed of, for example, an organic semiconductor material. The material for forming the charge-blocking layer 3 and the charge injection layer 5 is not limited to the organic semiconductor material and may be an oxide semiconductor, a nitride semiconductor, or the like or a composite material thereof.

The charge injection layer 5 may contain the same material as the charge-blocking layer 3. Alternatively, the material for forming the charge injection layer 5 may be the same material as the donor semiconductor material contained in the photoelectric conversion layer 4.

FIG. 2 is an exemplary energy band diagram in the photoelectric conversion element illustrated in FIG. 1. In FIG. 2, the energy band of each layer is indicated by a rectangle. In FIG. 2, an electron is indicated by a black circle, a hole is indicated by a white circle, and a portion of movement of the electron and the hole is schematically indicated.

The photoelectric conversion layer 4 generates an exciton in the interior in response to being irradiated with the light. The resulting exciton diffuses in the photoelectric conversion layer 4 and is dissociated into an electron and a hole at the interface between the acceptor semiconductor material and the donor semiconductor material. The resulting electron and hole move toward the lower electrode 2 or the upper electrode 6 in accordance with a voltage applied to the photoelectric conversion layer 4. When the voltage is applied between the upper electrode 6 and the lower electrode 2 so that the potential of the upper electrode 6 is higher than the potential of the lower electrode 2, the electron moves toward the upper electrode 6, and the hole moves toward the lower electrode 2. When the photoelectric conversion element 10 is used for an imaging apparatus, the hole is collected by the lower electrode 2 and is accumulated as a charge signal in a charge accumulation node electrically coupled to the lower electrode 2. The instance in which the hole moves toward the lower electrode 2 and in which the hole is used as a signal charge will be described below.

Herein, a material that provides another material with the electron of the pair of the electron and the hole generated due to absorption of light is referred to as a donor material, and a material that receives the electron is referred to as an acceptor material. In the present embodiment, the donor semiconductor material is a donor material, and the acceptor semiconductor material is an acceptor material. When two different types of organic semiconductor materials are used, the type that serves as a donor material and the type that serves as an acceptor material are generally determined in accordance with the relative position of the energy levels of the highest-occupied-molecular-orbital (HOMO) and the lowest-unoccupied-molecular-orbital (LUMO) of each of the two types of organic semiconductor materials at the contact interface. In FIG. 2, regarding the rectangle indicating energy band, the upper end denotes the energy level of the LUMO, and the lower end denotes the energy level of the HOMO. In this regard, the energy difference between the vacuum level and the energy level of the LUMO is referred to as electron affinity. In addition, the energy difference between the vacuum level and the energy level of the HOMO is referred to as an ionization potential. In FIG. 2, a lower position corresponds to higher electron affinity and a higher ionization potential.

As illustrated in FIG. 2, of the two types of semiconductor materials contained in the photoelectric conversion layer 4, the material having a shallow LUMO energy level, that is, having lower electron affinity, serves as a donor semiconductor material 4A which is the donor material. In addition, of the two types of semiconductor materials contained in the photoelectric conversion layer 4, the material having a deep LUMO energy level, that is, having higher electron affinity, serves as an acceptor semiconductor material 4B which is the acceptor material. In this regard, in FIG. 2, the energy band of the acceptor semiconductor material 4B illustrated in the drawing is shifted from the energy band of the donor semiconductor material 4A in the lateral direction. This is for the sake of visibility and does not mean that the donor semiconductor material 4A and the acceptor semiconductor material 4B are separately distributed in the thickness direction of the photoelectric conversion layer 4. Further, the energy bands of the acceptor semiconductor material 4B and the charge injection layer 5 are indicated by broken lines. This is also for the sake of visibility, and it is not intended to distinguish them from the solid rectangle.

The ionization potential of the donor semiconductor material 4A is, for example, lower than the ionization potential of the acceptor semiconductor material 4B.

The electron affinity of the charge-blocking layer 3 is, for example, lower than or equal to the electron affinity of the acceptor semiconductor material 4B of the photoelectric conversion layer 4. The charge-blocking layer 3 suppresses a charge (specifically an electron) from being injected from the lower electrode 2 to the photoelectric conversion layer 4. Consequently, noise signal which affects the signal noise ratio (SN ratio) can be decreased.

The ionization potential of the charge injection layer 5 is lower than or equal to the ionization potential of the acceptor semiconductor material 4B. The ionization potential of the charge injection layer 5 may be lower than the ionization potential of the acceptor semiconductor material 4B. The electron affinity of the charge injection layer 5 is lower than or equal to the electron affinity of the acceptor semiconductor material 4B. The electron affinity of the charge injection layer 5 may be lower than the electron affinity of the acceptor semiconductor material 4B.

As illustrated in FIG. 2, due to such a charge injection layer 5 that has an ionization potential lower than or equal to the ionization potential of the acceptor semiconductor material 4B being disposed, a portion of excitons generated in the acceptor semiconductor material 4B by the incident light is dissociated into an electron and a hole due to the hole moving to the charge injection layer 5 at the interface between the acceptor semiconductor material 4B and the charge injection layer 5. The hole moved to the charge injection layer 5 is moved to the donor semiconductor material 4A due to the above-described voltage being applied between the upper electrode 6 and the lower electrode 2. That is, the hole moved to the charge injection layer 5 is injected into the photoelectric conversion layer 4 again. Subsequently, the hole moved to the donor semiconductor material 4A performs hopping conduction in the photoelectric conversion layer 4 and is collected by the lower electrode 2 so as to be accumulated as a signal charge in the charge accumulation node. Therefore, since the hole separated at the interface between the acceptor semiconductor material 4B and the charge injection layer 5 is also utilized as a signal charge, the sensitivity of the photoelectric conversion element can be improved.

In addition, since the charge injection layer 5 having such a energy band can suppress a charge (specifically a hole) from being injected from the upper electrode 6 to the photoelectric conversion layer 4, noise signal which affects the SN ratio can be decreased. That is, the charge injection layer 5 has also a function of a charge-blocking layer for blocking a charge from the upper electrode 6.

A value obtained by subtracting the ionization potential of the charge injection layer 5 from the ionization potential of the donor semiconductor material 4A is less than a value obtained by subtracting the ionization potential of the donor semiconductor material 4A from the ionization potential of the charge-blocking layer 3. A barrier to hopping movement of the hole from the charge injection layer 5 to the donor semiconductor material 4A increases with an increase in the value obtained by subtracting the ionization potential of the charge injection layer 5 from the ionization potential of the donor semiconductor material 4A. In addition, a barrier to hopping movement of the hole from the donor semiconductor material 4A to the charge-blocking layer 3 increases with an increase in the value obtained by subtracting the ionization potential of the donor semiconductor material 4A from the ionization potential of the charge-blocking layer 3. Accordingly, in accordance with the above-described relationship with respect to the ionization potential, the barrier to hopping of the hole from the charge injection layer 5 to the donor semiconductor material 4A is lower than the barrier to hopping of the hole from the donor semiconductor material 4A to the charge-blocking layer 3. Consequently, since movement of the separated hole from the charge injection layer 5 to the donor semiconductor material 4A is not a rate-limiting factor of collection of the hole by the lower electrode 2, the hole is efficiently collected.

In this regard, the ionization potential of the charge injection layer 5 is higher than or equal to the ionization potential of, for example, the donor semiconductor material 4A. Accordingly, the separated hole readily moves from the charge injection layer 5 to the donor semiconductor material 4A.

The thickness of the charge-blocking layer 3 is, for example, greater than or equal to 2 nm or may be greater than or equal to 5 nm. Accordingly, a function of suppressing a charge from being injected from the lower electrode 2 is readily ensured. In addition, the thickness of the charge-blocking layer 3 is, for example, less than or equal to 50 nm or may be less than or equal to 20 nm. Accordingly, the photoelectric conversion efficiency of the photoelectric conversion element 10 can be suppressed from deteriorating.

The thickness of the charge injection layer 5 is, for example, greater than or equal to 2 nm or may be greater than or equal to 5 nm. Accordingly, a function of suppressing a charge from being injected from the upper electrode 6 is readily ensured. In addition, The thickness of the charge injection layer 5 is, for example, less than 50 nm or may be less than 20 nm. Accordingly, the charge injection layer 5 becoming difficult to absorb light is compatible with the sensitivity of the imaging apparatus being improved due to the exciton generated in the charge injection layer 5 diffusing and reaching the interface to the acceptor semiconductor material 4B of the photoelectric conversion layer 4. Consequently, the photoelectric conversion efficiency of the photoelectric conversion element 10 can be suppressed from deteriorating.

The light transmittance of the charge injection layer 5 is, for example, greater than or equal to 50% or may be greater than or equal to 70%. Accordingly, the photoelectric conversion efficiency of the photoelectric conversion element 10 can be suppressed from deteriorating. Herein, the light transmittance denotes an average value of the light transmittance in the range of the wavelength absorbed by the photoelectric conversion layer 4.

### Imaging Apparatus

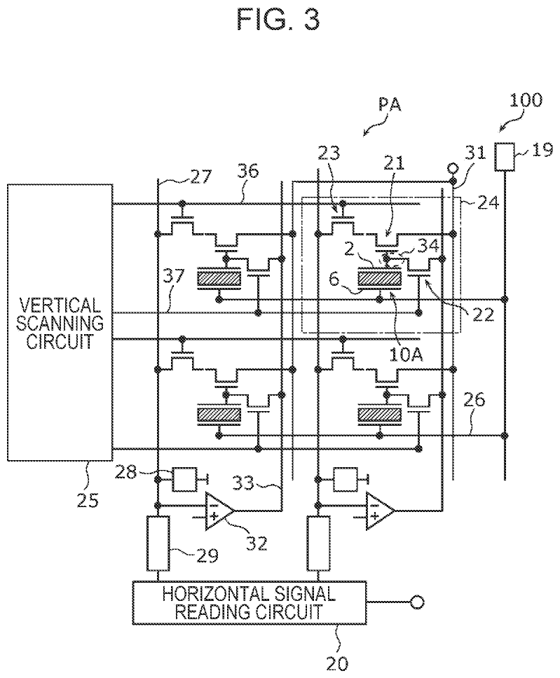

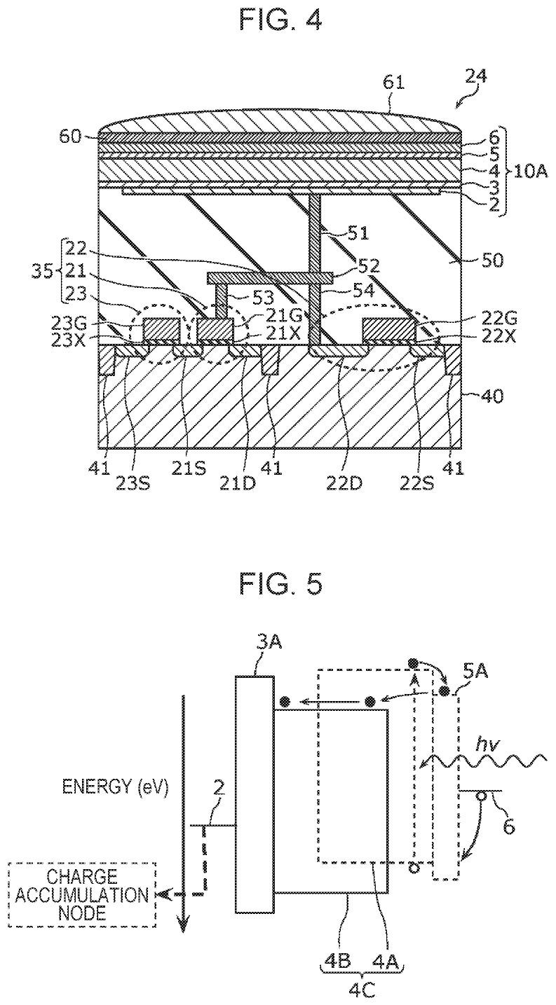

The imaging apparatus according to the present embodiment will be described below with reference to FIG. 3 and FIG. 4. FIG. 3 is a diagram illustrating an example of the circuit configuration of an imaging apparatus 100 incorporated with the photoelectric conversion portion 10A including the photoelectric conversion element 10 illustrated in FIG. 1. FIG. 4 is a schematic sectional view illustrating an example of a device structure of a pixel 24 in the imaging apparatus 100 according to the present embodiment.

As illustrated in FIG. 3 and FIG. 4, the imaging apparatus 100 according to the present embodiment includes a semiconductor substrate 40 and a plurality of pixels 24 cach including a charge detection circuit 35 provided to the semiconductor substrate 40, a photoelectric conversion portion 10A disposed above the semiconductor substrate 40, and a charge accumulation node 34 electrically coupled to the charge detection circuit 35 and the photoelectric conversion portion 10A, and the photoelectric conversion portion 10A of each of the plurality of pixels 24 includes the photoelectric conversion element 10. That is, each of the plurality of pixels 24 includes the upper electrode 6, the lower electrode 2, the photoelectric conversion layer 4, the charge injection layer 5, the charge-blocking layer 3, and the charge accumulation node 34. In the present embodiment, the charge accumulation node 34 is an example of the charge accumulation region.

In the photoelectric conversion portion 10A, the upper electrode 6, the charge injection layer 5, the photoelectric conversion layer 4, the charge-blocking layer 3, and the lower electrode 2 are arranged in this order from the light incident side of the photoelectric conversion portion 10A. The charge injection layer 5 is located on the light incident side of the photoelectric conversion layer 4. The light passed through the upper electrode 6 and the charge injection layer 5 is incident on the photoelectric conversion layer 4. Therefore, an exciton tends to be generated on the charge injection layer 5 side of the photoelectric conversion layer 4. In this regard, in the present embodiment, the light incident side of the photoelectric conversion portion 10A is opposite to the semiconductor substrate 40 side of the photoelectric conversion portion 10A.

The charge accumulation node 34 accumulates the charge obtained in the photoelectric conversion portion 10A, and the charge detection circuit 35 detects the charge accumulated in the charge accumulation node 34. In this regard, the charge detection circuit 35 provided to the semiconductor substrate 40 may be disposed on the semiconductor substrate 40 or disposed in the semiconductor substrate 40.

As illustrated in FIG. 3, the imaging apparatus 100 includes the plurality of pixels 24 and a peripheral circuit. The imaging apparatus 100 is, for example, an organic image sensor realized by a single chip integrated circuit and has an pixel array PA including a two-dimensionally arranged plurality of pixels 24.

The plurality of pixels 24 are arranged two-dimensionally, that is, in the row direction and the column direction, on the semiconductor substrate 40 and form a photosensitive region serving as a pixel region. FIG. 3 illustrates an example in which the pixels are arranged in a matrix of 2 rows and 2 columns. In this regard, for the convenience of illustration, a circuit (for example, a pixel electrode control circuit) to independently set the sensitivity of the pixel 24 is omitted from FIG. 3. The imaging apparatus 100 may be a line sensor. In such an instance, the plurality of pixels 24 may be one-dimensionally arranged. In the present specification, the row direction and the column direction denote the direction in which the row and the column, respectively, extend. That is, in FIG. 3, the longitudinal direction in the drawing is the column direction, and the lateral direction is the row direction.

As illustrated in FIG. 3 and FIG. 4, cach pixel 24 includes the charge accumulation node 34 electrically coupled to the photoelectric conversion portion 10A and the charge detection circuit 35. The charge detection circuit 35 includes an amplifying transistor 21, a reset transistor 22, and an address transistor 23.

The photoelectric conversion portion 10A includes the lower electrode 2 disposed as a pixel electrode and the upper electrode 6 disposed as a counter electrode facing the pixel electrode. The photoelectric conversion portion 10A includes the above-described photoelectric conversion element 10. A voltage to apply a predetermined bias voltage through a counter electrode signal line 26 is supplied to the upper electrode 6.

The lower electrode 2 is connected to a gate electrode 21G of the amplifying transistor 21, and the signal charge collected by the lower electrode 2 is accumulated in the charge accumulation node 34 located between the lower electrode 2 and the gate electrode 21G of the amplifying transistor 21. In the present embodiment, the signal charge is the hole. That is, the charge accumulation node 34 is electrically coupled to the lower electrode 2 and accumulates the hole of the exciton generated in the photoelectric conversion layer 4.

The signal charge accumulated in the charge accumulation node 34 serves as the voltage in accordance with the amount of the signal charge and is applied to the gate electrode 21G of the amplifying transistor 21. The amplifying transistor 21 amplifies the voltage, and the resulting signal charge is selectively read by the address transistor 23. The reset transistor 22 in which the source/drain electrode is connected to the lower electrode 2 resets the signal charge accumulated in the charge accumulation node 34. In other words, the reset transistor 22 resets the potentials of the gate electrode 21G of the amplifying transistor 21 and the lower electrode 2.

To selectively perform the above-described action in the plurality of pixels 24, the imaging apparatus 100 includes a power supply wiring line 31, a vertical signal line 27, an address signal line 36, and a reset signal line 37, and these lines are independently connected to each pixel 24. Specifically, the power supply wiring line 31 is connected to the source/drain electrode of the amplifying transistor 21 and the vertical signal line 27 is connected to a source/drain electrode of the address transistor 23. The address signal line 36 is connected to a gate electrode 23G of the address transistor 23. The reset signal line 37 is connected to a gate electrode 22G of the reset transistor 22.

The peripheral circuit includes a voltage supply circuit 19, a vertical scanning circuit 25, a horizontal signal reading circuit 20, a plurality of column signal processing circuits 29, a plurality of load circuits 28, and a plurality of differential amplifiers 32.

The voltage supply circuit 19 is electrically coupled to the upper electrode 6 through the counter electrode signal line 26. The voltage supply circuit 19 supplies a voltage to the upper electrode 6 so as to provide a potential difference between the upper electrode 6 and the lower electrode 2. When the signal charge is the hole, the voltage supply circuit 19 supplies a voltage to the upper electrode 6 so that the potential of the upper electrode 6 is higher than the potential of the lower electrode 2. In such an instance, the upper electrode 6 serves as an anode and the lower electrode 2 serves as a cathode. When the signal charge is the electron, the voltage supply circuit 19 supplies a voltage to the upper electrode 6 so that the potential of the upper electrode 6 is lower than the potential of the lower electrode 2. In such an instance, the upper electrode 6 serves as a cathode and the lower electrode 2 serves as an anode.

The vertical scanning circuit 25 is connected to the address signal line 36 and the reset signal line 37, selects, on a row basis, a plurality of pixels 24 arranged in a row, and performs reading of the signal voltage and resetting of the potential of the lower electrode 2. The power supply wiring line 31 serving as a source follower power supply supplies a predetermined power supply voltage to each pixel 24. The horizontal signal reading circuit 20 is electrically coupled to the plurality of column signal processing circuits 29. The column signal processing circuits 29 are electrically coupled to the pixels 24 arranged in the respective columns through the perpendicular signal lines 27 corresponding to the respective columns. The load circuit 28 and the amplifying transistor 21 form the source follower circuit.

The plurality of differential amplifiers 32 are disposed corresponding to the respective columns. The inverting input terminal of the differential amplifier 32 is connected to the corresponding perpendicular signal line 27. The output terminal of the differential amplifier 32 is connected to pixels 24 through a feedback line 33 corresponding to each column.

The vertical scanning circuit 25 applies a row selection signal for controlling on and off of the address transistor 23 to the gate electrode 23G of the address transistor 23 through the address signal line 36. Accordingly, a reading target row is scanned and selected. The signal voltage is read from the pixel 24 in the selected row to the vertical signal line 27. The vertical scanning circuit 25 applies a reset signal for controlling on and off of the reset transistor 22 to the gate electrode 22G of the reset transistor 22 through the reset signal line 37. Accordingly, a reset action target row of the pixel 24 is selected. The vertical signal line 27 transmits the signal voltage read from the pixel 24 selected by the vertical scanning circuit 25 to the column signal processing circuit 29.

The column signal processing circuit 29 performs noise suppression signal processing represented by correlated double sampling, analog-digital conversion (AD conversion), and the like.

The horizontal signal reading circuit 20 sequentially reads signals from the plurality of column signal processing circuits 29 to the horizontal common signal line (not illustrated in the drawing).

The differential amplifier 32 is connected to the drain electrode of the reset transistor 22 through the feedback line 33. Therefore, the differential amplifier 32 receives the output value of the address transistor 23 by the inverting input terminal. The differential amplifier 32 performs feedback action so that the gate potential of the amplifying transistor 21 is set to be a predetermined feedback voltage. In such an instance, the output voltage value of the differential amplifier 32 is 0 V or a positive voltage in the vicinity of 0 V. The feedback voltage denotes the output voltage of the differential amplifier 32.

As illustrated in FIG. 4, the pixel 24 includes the semiconductor substrate 40, the charge detection circuit 35, the photoelectric conversion portion 10A, and the charge accumulation node 34 (refer to FIG. 3).

The semiconductor substrate 40 may be an insulating substrate or the like in which a semiconductor layer is disposed on the photosensitive-region-formation-side surface and may be, for example, a p-type silicon substrate. The semiconductor substrate 40 includes impurity regions 21D, 21S, 22D, 22S, and 23S and an element isolation region 41 to isolate pixels 24 from each other. The impurity regions 21D, 21S, 22D, 22S, and 23S are, for example, n-type regions. Herein, the element isolation region 41 is disposed between the impurity region 21D and the impurity region 22D. Accordingly, the signal charge accumulated in the charge accumulation node 34 can be suppressed from leaking. In this regard, the element isolation region 41 is formed by, for example, performing acceptor ion implantation under a predetermined condition.

The impurity regions 21D, 21S, 22D, 22S, and 23S are, for example, diffusion regions formed in the semiconductor substrate 40. As illustrated in FIG. 4, the amplifying transistor 21 includes the impurity region 21S, the impurity region 21D, and the gate electrode 21G. The impurity region 21S and the impurity region 21D function as, for example, the source region and the drain region, respectively, of the amplifying transistor 21. The channel region of the amplifying transistor 21 is formed between the impurity region 21S and the impurity region 21D.

Likewise, the address transistor 23 includes the impurity region 23S, the impurity region 21S, and the gate electrode 23G connected to the address signal line 36. In the present example, the amplifying transistor 21 and the address transistor 23 are electrically coupled to each other by sharing the impurity region 21S. The impurity region 23S functions as, for example, the source region of the address transistor 23. The impurity region 23S is connected to the vertical signal line 27 illustrated in FIG. 3.

The reset transistor 22 includes the impurity regions 22D and 22S and gate electrode 22G connected to the reset signal line 37. The impurity region 22S functions as, for example, the source region of the reset transistor 22. The impurity region 22S is connected to the feedback line 33 illustrated in FIG. 3.

An interlayer insulating layer 50 is stacked on the semiconductor substrate 40 so as to cover the amplifying transistor 21, the address transistor 23, and the reset transistor 22.

In addition, a wiring layer (not illustrated in the drawing) may be arranged in the interlayer insulating layer 50. The wiring layer is formed of, for example, metal such as copper and may include wiring lines, such as the above-described vertical signal line 27, in a portion thereof. The number of insulating layers in the interlayer insulating layer 50 and the number of wiring layers arranged in the interlayer insulating layer 50 can be optionally set.

In the interlayer insulating layer 50, a contact plug 53 connected to the gate electrode 21G of the amplifying transistor 21, a contact plug 54 connected to the impurity region 22D of the reset transistor 22, a contact plug 51 connected to the lower electrode 2, and a wiring line 52 to connect the contact plug 51, the contact plug 54, and the contact plug 53. Consequently, the impurity region 22D of the reset transistor 22 is electrically coupled to the gate electrode 21G of the amplifying transistor 21. In the configuration illustrated in FIG. 4, the contact plugs 51, 53, and 54, the wiring line 52, the gate electrode 21G of the amplifying transistor 21, and the impurity region 22D of the reset transistor 22 constitute at least a portion of the charge accumulation node 34.

The charge detection circuit 35 detects the signal charge collected by the lower electrode 2 and outputs a signal voltage. The charge detection circuit 35 includes the amplifying transistor 21, the reset transistor 22, and the address transistor 23 and is provided to the semiconductor substrate 40.

The amplifying transistor 21 is formed in the semiconductor substrate 40 and includes the impurity region 21D and the impurity region 21S functioning as the drain electrode and the source electrode, respectively, a gate insulating layer 21X formed on the semiconductor substrate 40, and the gate electrode 21G formed on the gate insulating layer 21X.

The reset transistor 22 is formed in the semiconductor substrate 40 and includes the impurity region 22D and the impurity region 22S functioning as the drain electrode and the source electrode, respectively, a gate insulating layer 22X formed on the semiconductor substrate 40, and the gate electrode 22G formed on the gate insulating layer 22X.

The address transistor 23 is formed in the semiconductor substrate 40 and includes the impurity region 21S and the impurity region 23S functioning as the drain electrode and the source electrode, respectively, a gate insulating layer 23X formed on the semiconductor substrate 40, and the gate electrode 23G formed on the gate insulating layer 23X. The impurity region 21S is connected to the amplifying transistor 21 in series and to the address transistor 23 in series.

The photoelectric conversion portion 10A is arranged on the interlayer insulating layer 50. In other words, in the present embodiment, a plurality of pixels 24 constituting the pixel array PA are formed on the semiconductor substrate 40. The plurality of pixels 24 two-dimensionally arranged on the semiconductor substrate 40 form a photosensitive region. The distance between two pixels 24 connected to each other (that is, pixel pitch) may be, for example, about 2 μm.

The photoelectric conversion portion 10A has the structure of the above-described photoelectric conversion element 10.

A color filter 60 is formed above the photoelectric conversion portion 10A, and a microlens 61 is formed above the color filter 60. The color filter 60 is formed as, for example, an on-chip color filter through patterning. Regarding the material for forming the color filter 60, a photosensitive resin or the like in which a dye or a pigment is dispersed is used. The microlens 61 is formed as, for example, an on-chip microlens. Regarding the material for forming the microlens 61, an ultraviolet-sensitive material or the like is used.

Regarding the imaging apparatus 100, a common semiconductor production process can be used. In particular, when a silicon substrate is used as the semiconductor substrate 40, the imaging apparatus 100 can be produced by utilizing various silicon semiconductor processes.

The imaging apparatus 100 may action in a rolling shutter system in which a plurality of pixels 24 are sequentially exposed, for example, on a row basis so as to read a signal or action in a global shutter system in which the exposure periods of a plurality of pixels 24 are unified. When the action is performed in the rolling shutter system, for example, the voltage supply circuit 19 continues supplying a first voltage which generates sensitivity in the photoelectric conversion portion 10A to the upper electrode 6 during imaging, and an action of reading the signal charge is sequentially performed on a pixel row basis. When the action is performed in the global shutter system, for example, the voltage supply circuit 19 supplies the first voltage to the upper electrode 6 during the exposure period and supplies a second voltage which does not generate sensitivity in the photoelectric conversion portion 10A to the upper electrode 6 during a non-exposure period. An action of reading the signal charge is sequentially performed on a pixel row basis during the non-exposure period. In this regard, the reading action of the imaging apparatus 100 is not limited to such an action, and a reading action of a known imaging apparatus may be applied.

The signal charge detected by the imaging apparatus 100 may be the electron. In such an instance, the charge accumulation node 34 electrically coupled to the lower electrode 2 accumulates the electron. FIG. 5 is an exemplary energy band diagram in another photoelectric conversion element according to the present embodiment. In FIG. 5, the energy band of each layer is indicated by a rectangle. In FIG. 5, an electron is indicated by a black circle, a hole is indicated by a white circle, and a portion of movement of the electron and the hole is schematically indicated. In this regard, in FIG. 5, the energy band of the acceptor semiconductor material 4B illustrated in the drawing is shifted from the energy band of the donor semiconductor material 4A in the lateral direction. This is for the sake of visibility and does not mean that the donor semiconductor material 4A and the acceptor semiconductor material 4B are separately distributed in the thickness direction of a photoelectric conversion layer 4C. Further, the energy bands of the donor semiconductor material 4A and the charge injection layer 5A are indicated by broken lines. This is also for the sake of visibility, and it is not intended to distinguish them from the solid rectangle.

In FIG. 5, as another example of the photoelectric conversion element in the imaging apparatus according to the present embodiment, the energy band of a photoelectric conversion element including a photoelectric conversion layer 4C, a charge-blocking layer 3A, and a charge injection layer 5A instead of the photoelectric conversion layer 4, the charge-blocking layer 3, and the charge injection layer 5 in the above-described photoelectric conversion element 10 is illustrated.

The ionization potential of the charge-blocking layer 3A is, for example, higher than or equal to the ionization potential of the donor semiconductor material 4A of the photoelectric conversion layer 4C. The charge-blocking layer 3A suppresses a charge (specifically a hole) from being injected from the lower electrode 2 to the photoelectric conversion layer 4C. Consequently, noise signal which affects the SN ratio can be decreased.

The electron affinity of the charge injection layer 5A is higher than or equal to the electron affinity of the donor semiconductor material 4A. The electron affinity of the charge injection layer 5A may be higher than the electron affinity of the donor semiconductor material 4A. The ionization potential of the charge injection layer 5A is higher than or equal to the ionization potential of the donor semiconductor material 4A. The ionization potential of the charge injection layer 5A may be higher than the ionization potential of the donor semiconductor material 4A.

As illustrated in FIG. 5, due to such a charge injection layer 5A that has electron affinity higher than or equal to the electron affinity of the donor semiconductor material 4A being disposed, a portion of excitons generated in the donor semiconductor material 4A by the incident light is dissociated into an electron and a hole due to the electron moving to the charge injection layer 5A at the interface between the donor semiconductor material 4A and the charge injection layer 5A. The electron thus moved to the charge injection layer 5A is collected by the lower electrode 2 through the acceptor semiconductor material 4B and is accumulated as a signal charge in the charge accumulation node by the mechanism akin to that of the above-described photoelectric conversion element 10. Therefore, since the electron separated at the interface between the donor semiconductor material 4A and the charge injection layer 5A is also utilized as a signal charge, the sensitivity of the photoelectric conversion element 10 can be improved.

In addition, since the charge injection layer 5A having such a energy band can suppress a charge (specifically an electron) from being injected from the upper electrode 6 to the photoelectric conversion layer 4C, noise signal which affects the SN ratio can be decreased.

A value obtained by subtracting the electron affinity of the charge injection layer 5A from the electron affinity of the acceptor semiconductor material 4B is, for example, greater than a value obtained by subtracting the electron affinity of the acceptor semiconductor material 4B from the electron affinity of the charge-blocking layer 3A. A barrier to hopping movement of the electron from the charge injection layer 5A to the acceptor semiconductor material 4B increases with a decrease in the value obtained by subtracting the electron affinity of the charge injection layer 5A from the electron affinity of the acceptor semiconductor material 4B. In addition, a barrier to hopping movement of the electron from the acceptor semiconductor material 4B to the charge-blocking layer 3A increases with a decrease in the value obtained by subtracting the electron affinity of the acceptor semiconductor material 4B from the electron affinity of the charge-blocking layer 3A. According to the above-described relationship with respect to the electron affinity, the barrier to hopping of the electron from the charge injection layer 5A to the acceptor semiconductor material 4B is lower than the barrier to hopping of the electron from the acceptor semiconductor material 4B to the charge-blocking layer 3A. Consequently, since movement of the separated electron from the charge injection layer 5A to the acceptor semiconductor material 4B is not a rate-limiting factor of collection of the electron by the lower electrode 2, the electron is efficiently collected.

In this regard, the electron affinity of the charge injection layer 5A is, for example, lower than or equal to the electron affinity of the acceptor semiconductor material 4B. Accordingly, the separated electron readily moves from the charge injection layer 5A to the acceptor semiconductor material 4B.

The proportion of the donor semiconductor material 4A in the photoelectric conversion layer 4C is, for example, 70% or more. In addition, the acceptor semiconductor material 4B in the photoelectric conversion layer 4C is, for example, less than or equal to 50% of the donor semiconductor material 4A. Consequently, since the contact interface between the donor semiconductor material 4A and the charge injection layer 5A increases, an effect of improving the sensitivity is obtained more significantly. In this regard, the proportion of the material is, for example, a volume proportion but may be a weight proportion.

### EXAMPLES

The photoelectric conversion element included in the imaging apparatus according to the present disclosure will be specifically described below with reference to examples, but the present disclosure is not limited to only the following examples. In particular, a photoelectric conversion element included in the imaging apparatus according to the embodiment of the present disclosure and a photoelectric conversion element to compare the characteristics were produced, and spectral sensitivity was measured. Production of photoelectric conversion element

### Example 1

A substrate produced by forming a TiN film was used as a support substrate. TiN having a work function of 4.7 eV were used as a lower electrode, and a charge-blocking layer was formed on the lower electrode by forming a film of 9,9′-[1,1′-biphenyl]-4,4′-diylbis[3,6-bis(1,1-dimethyl ethyl)]-9H-carbazole by a vacuum vapor deposition method. Subsequently, a photoelectric conversion layer was formed on the charge-blocking layer by a vapor deposition method in which subphthalocyanine serving as a material for forming a donor semiconductor material and fullerene C60 serving as a material for forming an acceptor semiconductor material were used as the materials for forming the photoelectric conversion layer and co-evaporated. The volume ratio of the donor semiconductor material to the acceptor semiconductor material was 1:3. In such an instance, the thickness of the resulting photoelectric conversion layer was about 500 nm. Subphthalocyanine in which a center metal was boron (B) and a chloride ion serving as a ligand was coordinated to B was used as the subphthalocyanine.

A charge injection layer was formed on the photoelectric conversion layer by vapor-depositing 5 nm of subphthalocyanine serving as a material for forming the charge injection layer by a vacuum vapor deposition method using a metal shadow mask.

An ITO film having a thickness of 30 nm and serving as an upper electrode was formed on the charge injection layer by a sputtering method, and thereafter an Al₂O₃ film serving as a sealing film was further formed on the upper electrode by an atomic layer deposition method so as to obtain a photoelectric conversion element.

### Example 2

A photoelectric conversion element was obtained by performing the steps akin to the steps in Example 1 except that 9,9′-[1,1′-biphenyl]-4,4′-diylbis[3,6-bis(1,1-dimethyl ethyl)]-9H-carbazole instead of subphthalocyanine was used as the material for forming the charge injection layer.

### Comparative Example 1

A photoelectric conversion element was obtained by performing the steps akin to the steps in Example 1 except that the charge injection layer was not formed and the upper electrode was formed directly on the photoelectric conversion layer.

### Measurement of Ionization Potential and Electron Affinity of Material

The ionization potential and the electron affinity of each of materials used in Example 1, Example 2, and Comparative example 1 were measured.

Regarding the measurement of the ionization potential, a specimen in which a film of each of materials used in Example 1, Example 2, and Comparative example 1 was formed on a glass substrate provided with an ITO film was prepared. Subsequently, the number of photoelectrons was measured by using Photoemission Yield Spectroscopy in Air (AC-3, produced by RIKEN KEIKI Co., Ltd.) where ultraviolet irradiation energy was changed, and the energy position when a photoelectron was detected for the first time was assumed to be the ionization potential.

Regarding the measurement of the electron affinity, a specimen in which a film of each of materials used in Example 1, Example 2, and Comparative example 1 was formed on a quartz substrate was prepared. Subsequently, an absorption spectrum of the prepared specimen was measured by using Spectrophotometer (U4100, produced by Hitachi High-Technologies Corporation), and an optical band gap was calculated from the result of the absorption edge of the obtained absorption spectrum. The electron affinity was estimated by subtraction between the ionization potential obtained by the above-described measurement of the ionization potential and the calculated optical band gap.

Table 1 presents the ionization potential and the electron affinity of each of the materials used in Example 1, Example 2, and Comparative example 1.

TABLE 1

| | | | Ionization | Electron |
|---|---|---|---|---|
| | | | potential | affinity |
| Layer | | Material | (eV) | (eV) |
| Charge-blocking layer | | 9,9′-[1,1′-biphenyl]-4,4′- | 5.8 | 2.7 |
| | | diylbis[3,6-bis(1,1-dimethyl | | |
| | | ethyl)]-9H-carbazole | | |
| Photoelectric | Acceptor | fullerene C60 | 6.2 | 4.2 |
| conversion | semiconductor | | | |
| layer | material | | | |
| | Donor | subphthalocyanine | 5.5 | 3.4 |
| | semiconductor | | | |
| | material | | | |
| Charge | Example 1 | subphthalocyanine | 5.5 | 3.4 |
| injection | Example 2 | 9,9′-[1,1′-biphenyl]-4,4′- | 5.8 | 2.7 |
| layer | | diylbis[3,6-bis(1,1-dimethyl | | |
| | | ethyl)]-9H-carbazole | | |

As presented in Table 1, regarding the photoelectric conversion elements in Example 1 and Example 2, the ionization potential of the charge injection layer is lower than or equal to the ionization potential of the acceptor semiconductor material, and the electron affinity of the charge injection layer is lower than or equal to the electron affinity of the acceptor semiconductor material. In addition, regarding the photoelectric conversion elements in Example 1 and Example 2, the value obtained by subtracting the ionization potential of the charge injection layer from the ionization potential of the donor semiconductor material is less than or equal to 0 and is less than the value obtained by subtracting the ionization potential of the donor semiconductor material from the ionization potential of the charge-blocking layer.

### Measurement of Spectral Sensitivity

Regarding the photoelectric conversion elements in Example 1, Example 2, and Comparative example 1, the external quantum efficiency was measured as an indicator of the spectral sensitivity. Specifically, the photoelectric conversion element was introduced into a measurement jig which could be sealed in a glove box in a nitrogen atmosphere, and the external quantum efficiency of the photoelectric conversion element at 500 nm was measured by using Spectral Resonance Measurement system (produced by Bunkoukeiki Co., Ltd.) under the condition in which a voltage of 5 V was applied. Regarding measurement of the external quantum efficiency, the voltage was applied so that the potential of the upper electrode was higher than the potential of the lower electrode. That is, the external quantum efficiency of the photoelectric conversion element was measured under the condition in which the electron was moved to the upper electrode and the hole was moved to the lower electrode. Then, the relative external quantum efficiency that was the ratio of the external quantum efficiency relative to the external quantum efficiency of Comparative example 1 was calculated by the following formula.

relative external quantum efficiency (%)=external quantum efficiency of photoelectric conversion element/external quantum efficiency of Comparative example 1×100

Table 2 presents the measurement results of the relative external quantum efficiencies of the photoelectric conversion elements in Example 1, Example 2, and Comparative example 1.

TABLE 2

| | | Relative external |
|---|---|---|
| | | quantum efficiency |
| | Charge injection layer | (%) |
| Comparative | none | 100 |
| example 1 | | |
| Example 1 | subphthalocyanine | 108 |
| Example 2 | 9,9′-[1,1′-biphenyl]-4,4′- | 105 |
| | diylbis[3,6-bis(1,1-dimethyl | |
| | ethyl)]-9H-carbazole | |

As presented in Table 2, the relative external quantum efficiencies in Example 1 and Example 2 are higher than that in Comparative example 1. It is conjectured that, regarding the photoelectric conversion elements in Example 1 and Example 2, since the ionization potential of the charge injection layer is lower than or equal to the ionization potential of the acceptor semiconductor material, the hole separated between the charge injection layer and the acceptor semiconductor material contributes to the sensitivity so as to obtain the sensitivity higher than that in Comparative example 1 in which the charge injection layer is not formed.

Accordingly, it is indicated that the photoelectric conversion element having high sensitivity can be realized by the configuration of the photoelectric conversion element according to the present disclosure.

The imaging apparatus according to the present disclosure is described above with reference to the embodiments and the examples, but the present disclosure is not limited to the embodiments and the examples. The embodiment and the example including various modifications conceived by a person skilled in the art and other embodiments constructed by combining some constituent elements of the embodiments and the examples are included in the scope of the present disclosure without departing from the spirit of the present disclosure.

The imaging apparatus according to the present disclosure can be applied to various camera systems and sensor systems, such as medical cameras, surveillance cameras, on-vehicle cameras, ranging cameras, microscope cameras, drone cameras, and robot cameras.

What is claimed is:

1. An imaging apparatus comprising:
a first electrode;
a second electrode facing the first electrode;
a photoelectric conversion layer that is located between the first electrode and the second electrode, that contains a donor semiconductor material and an acceptor semiconductor material, and that generates a pair of an electron and a hole;
a charge injection layer located between the first electrode and the photoelectric conversion layer; and
a charge accumulation region that is electrically coupled to the second electrode and that accumulates the hole, wherein
an ionization potential of the charge injection layer is less than or equal to an ionization potential of the acceptor semiconductor material,
electron affinity of the charge injection layer is less than or equal to electron affinity of the acceptor semiconductor material, and
light transmittance of the charge injection layer is greater than or equal to 70%.

2. The imaging apparatus according to claim 1,
wherein a volume proportion of the acceptor semiconductor material in the photoelectric conversion layer is greater than or equal to 70%.

3. The imaging apparatus according to claim 1, further comprising a charge-blocking layer located between the second electrode and the photoelectric conversion layer,
wherein a value obtained by subtracting the ionization potential of the charge injection layer from an ionization potential of the donor semiconductor material is less than a value obtained by subtracting the ionization potential of the donor semiconductor material from an ionization potential of the charge-blocking layer.

4. An imaging apparatus comprising:
a first electrode;
a second electrode facing the first electrode;
a photoelectric conversion layer that is located between the first electrode and the second electrode, that contains a donor semiconductor material and an acceptor semiconductor material, and that generates a pair of an electron and a hole;
a charge injection layer located between the first electrode and the photoelectric conversion layer; and
a charge accumulation region that is electrically coupled to the second electrode and that accumulates the electron, wherein
electron affinity of the charge injection layer is greater than or equal to electron affinity of the donor semiconductor material,
an ionization potential of the charge injection layer is greater than or equal to an ionization potential of the donor semiconductor material, and
light transmittance of the charge injection layer is greater than or equal to 70%.

5. The imaging apparatus according to claim 4,
wherein a volume proportion of the donor semiconductor material in the photoelectric conversion layer is greater than or equal to 70%.

6. The imaging apparatus according to claim 4, further comprising a charge-blocking layer located between the second electrode and the photoelectric conversion layer,
wherein a value obtained by subtracting the electron affinity of the charge injection layer from electron affinity of the acceptor semiconductor material is greater than a value obtained by subtracting the electron affinity of the acceptor semiconductor material from electron affinity of the charge-blocking layer.

7. The imaging apparatus according to claim 4,
wherein light transmittance in a visible light region of the charge injection layer is greater than or equal to 70%.

8. The imaging apparatus according to claim 1,
wherein a thickness of the charge injection layer is greater than or equal to 2 nm.

9. The imaging apparatus according to claim 1,
wherein a thickness of the charge injection layer is less than 20 nm.

10. An imaging apparatus comprising:
a first electrode;
a second electrode facing the first electrode;
a photoelectric conversion layer that is located between the first electrode and the second electrode, that contains a donor semiconductor material and an acceptor semiconductor material, and that generates a pair of an electron and a hole;
a charge injection layer located between the first electrode and the photoelectric conversion layer; and
a charge accumulation region that is electrically coupled to the second electrode and that accumulates the hole, wherein
an ionization potential of the charge injection layer is less than or equal to an ionization potential of the acceptor semiconductor material,
electron affinity of the charge injection layer is less than or equal to electron affinity of the acceptor semiconductor material, and
a thickness of the charge injection layer is greater than or equal to 2 nm and less than 20 nm.
